(19) United States
(12) Patent Application Publication
(10) Pub. No.: US 2025/0351735 A1
(43) Pub. Date: Nov. 13, 2025

(54) SEMICONDUCTOR MEMORY DEVICE AND METHOD FOR FABRICATING THE SAME

(71) Applicant: TAIWAN SEMICONDUCTOR MANUFACTURING COMPANY LTD., HSINCHU (TW)

(72) Inventors: ZHI-REN XIAO, HSINCHU COUNTY (TW); NUO XU, SAN JOSE, CA (US); PO-SHENG LU, HSINCHU CITY (TW); ZHIQIANG WU, HSINCHU COUNTY (TW); KATHERINE H. CHIANG, NEW TAIPEI CITY (TW); YU-JEN WANG, HSINCHU CITY (TW)

(21) Appl. No.: 18/660,264

(22) Filed: May 10, 2024

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A semiconductor memory structure is provided. The semiconductor memory structure includes a bottom electrode, a base stack, a magnetic stack, a capping layer and a top electrode stacking along a first direction. The magnetic stack includes two or more free layers separated by one or more spacer layers. Each of the spacer layers is sandwiched by two of the two or more free layers. The spacer layers include a metal oxide, the atoms in which would not diffuse into the free layers during annealing procedure. Therefore, the spacer layers can improve exchange coupling (Aₑₓ) and thermal stability in the resulting multilayer magnetic stack.

### BACKGROUND

Many modern-day electronic devices contain electronic memory. Electronic memory may be volatile memory or non-volatile memory. Non-volatile memory is able to store data in the absence of power, whereas volatile memory is not. Magnetic random-access memory (MRAM) is one promising candidate for next generation electronic memory due to advantages over current electronic memory. Compared to current non-volatile memory, such as flash random-access memory, MRAM typically is faster and has better endurance. Compared to current volatile memory, such as dynamic random-access memory (DRAM) and static random-access memory (SRAM), MRAM typically has similar performance and density, but lower power consumption.

### BACKGROUND BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a fragmentary cross-sectional view of a semiconductor memory structure in accordance with some embodiments of the present disclosure.

FIG. 2 is a fragmentary cross-sectional view of a semiconductor memory structure in accordance with some another embodiments of the present disclosure.

FIG. 3 is a fragmentary cross-sectional view of a semiconductor memory structure in accordance with some another embodiments of the present disclosure.

FIG. 4A shows a distribution of atoms in a magnetic stack of a semiconductor memory structure before performing an annealing process in accordance with some embodiments of the present disclosure.

FIG. 4B shows a distribution of atoms in a magnetic stack of a semiconductor memory structure after performing an annealing process in accordance with some embodiments of the present disclosure.

FIG. 5 is a partially enlarged view of an area A shown in FIG. 4B in accordance with some embodiment of the present disclosure.

FIG. 6 is a plot showing an improved performance achieved by the presence of a MgO spacer layer in a magnetic stack of a semiconductor memory structure in accordance with some embodiments of the present disclosure.

FIG. 7 is a flowchart illustrating a method of fabricating a semiconductor memory structure in accordance with some embodiment of the present disclosure.

FIGS. 8A to 8F illustrate diagrammatic cross-sectional side views of some embodiments of a semiconductor memory structure at various stages of fabrication, according to the method of FIG. 7.

FIGS. 9A to 9E illustrate diagrammatic cross-sectional side views of some embodiments of a semiconductor memory structure at various stages of fabrication, according to the method of FIG. 7.

FIGS. 10A to 10F illustrate diagrammatic cross-sectional side views of some embodiments of a semiconductor memory structure at various stages of fabrication, according to the method of FIG. 7.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Also, the components disclosed herein may be arranged, combined, or configured in ways different from the exemplary embodiments shown herein without departing from the scope of the present disclosure. It is understood that those skilled in the art will be able to devise various equivalents that, although not explicitly described herein, embody the principles of the present invention.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

In many instances, MRAM structures are embedded in a metallization layer prepared in a back-end-of-line (BEOL) operation, whereas transistors are fabricated in a front-end-of-line (FEOL) operation. The MRAM structures may be embedded in any position of the metallization layer over the transistors. Within an MRAM structure, a magnetic tunnel junction (MTJ) is a device that changes its resistive state based on the state of magnetic materials within the device.

For an MTJ within a MRAM or spin-transfer torque (STT)-MRAM, several layers are stacked to form the MTJ, in which magnetic layers (also called “free layers”) may be separated by metal, such as heavy metal as a lubricant to release strain in order to facilitate re-crystallization of free layers during annealing process. However, metal would be dissolved and diffused into other layers during annealing process, and would re-agglomerate into islands after annealing process, which causes process variability. Therefore, inserting metal between the free layers severely damages magnetic properties such as interfacial perpendicular magnetization anisotropy (IPMA), exchange coupling (Aₑₓ), tunnel magnetoresistance (TMR), saturation magnetization (Ms) and so on, and thus degrades MRAM's performance. There is a need to seek a semiconductor memory structure with enhanced performance. Therefore, there is a need to provide a semiconductor memory structure with little diffusion of metal into free layers and thus to achieve improved iPMA, Aₑₓ and other properties.

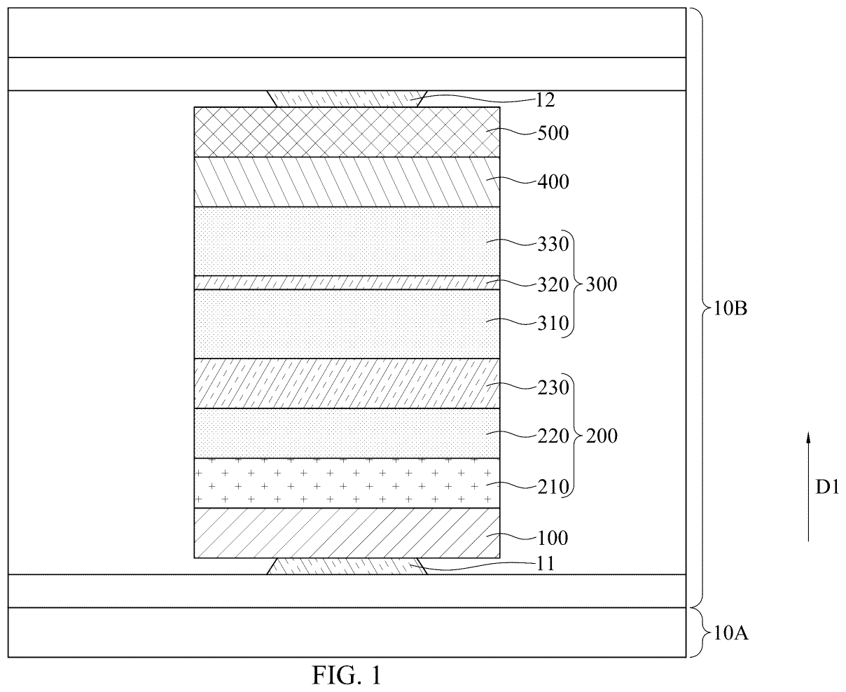

FIG. 1 illustrates a cross-sectional view of a semiconductor memory structure according to some embodiments of the present disclosure. The semiconductor memory structure is formed in a BEOL metallization stack 10B stacking on a FEOL metallization stack 10A and includes a bottom electrode 100, a base stack 200, a magnetic stack 300, a capping layer 400 and a top electrode 500 stacking along a first direction D1.

The bottom electrode 100 may be electrically coupled to a first metallization layer (not shown) of the BEOL metallization stack 10A through a first via 11. The first via 11 may extend from the bottom electrode 100, through an etch stop layer, to the metallization layer of the BEOL metallization stack 10A. The first via 11 may be, for example, a metal, such as copper, gold or tungsten. The bottom electrode 100 may be formed of a conductive material, such as, for example, titanium nitride, tantalum nitride, titanium (Ti), tantalum (Ta), ruthenium (Ru), platinum (Pt), tungsten (W), aluminum (Al), copper (Cu), or a combination of one or more of the foregoing. Further, a thickness of the bottom electrode layer 100 may be, for example, about 10 nm to about 100 nm. An exemplary formation method of the bottom electrode layer 100 includes sputtering, physical vapor deposition (PVD), atomic layer deposition (ALD), e-beam or thermal evaporation, or the like.

The base stack 200 is disposed on the bottom electrode 100 and has a plurality of layers, as shown in FIG. 1, including a seed layer 210, a reference layer 220 and a barrier layer 230.

The seed layer 210 is disposed on the bottom electrode 100 and may be a single layer or multilayer made of one or more metals or alloys that promote a uniform thickness in overlying layers and to maintain or enhance PMA, axis coercivity (Hc), and uniaxial anisotropy (Hk) in overlying magnetic layers. In some embodiments, as shown in FIG. 1, the seed layer 210 is a single layer and may comprise Ta, Zr, Nb, Ru, Mg, Sr, Ti, Al, V, Hf, B, Si, TaN, ZrN, NbN, NiCr, MgZr, MgNb, NiFeCr, or a combination thereof. In some alternative embodiments, the seed layer 210 may be a composite (not shown) including, for example but not limited thereto, a lower layer made of one or more of Ta, Zr, Nb, TaN, ZrN, NbN, and Ru and an upper layer made of one or more of Mg, Sr, Ti, Al, V, Hf, B, Si, or an alloy of Mg with Zr or Nb. The lower layer promotes a uniform thickness, (111) crystal structure, and smooth top surfaces in overlying layers. The (111) texture of upper layer is advantageously used to induce a (111) texture in an overlying magnetic layer (e.g., the reference layer 220 as shown in FIG. 1). The seed layer 210 may be used to maintain or enhance PMA, Hc, and Hk in overlying magnetic stack 300.

The reference layer 220 stacks on the seed layer 210. The reference layer 220 may be a ferromagnetic layer having a “fixed” magnetization direction. As an example, the magnetization direction of the reference layer 220 may be “up”, i.e. the first direction D1. In some embodiments, the reference layer 220 may have intrinsic PMA that is enhanced by contact with an appropriate seed layer along a bottom surface of the reference layer 220. In some embodiments, the reference layer 220 may include Co, CoFeB, or another alloy comprising two or more of Co, Fe, Ni, and B. In some embodiments, the reference layer 220 may be a multilayer structure represented by (Ni/Co), where n is the lamination number that is from 2 to 30, each Ni layer has a thickness of about 6 Angstroms, and each Co layer has a thickness of about 2.5 Angstroms. Optionally, Ni may be replaced by NiFe or NiCo, and Co may be replaced by CoFe in the laminated stack. In some embodiments, the reference layer may be any face centered cubic (FCC) magnetic layer such as (Co/Pt) n, (Co/Pd) n, (Fe/Pt) n, or (Fe/Pd) n having PMA. The magnetic element may also include a transitional layer made of CoFeB, CoFe, or Co between the reference layer 220 and the barrier layer 230. In addition, the reference layer 220 may be modified to a synthetic anti-ferromagnetic (SAF) configuration wherein a non-magnetic coupling layer such as Ru is sandwiched between two laminated (Ni/Co) stacks, for example.

The barrier layer 230 stacks on the reference layer 220 and is arranged abutting and between the magnetic stack 300 and the reference layer 220. The barrier layer 230 provides electrical isolation between the magnetic stack 300 and the reference layer 220, while still allowing electrons to tunnel through the barrier layer 230 under proper conditions. The barrier layer 230 may be a single layer including, for example, magnesium oxide (MgO), aluminum oxide (AlOₓ), titanium oxide (TiOₓ), zinc oxide (ZnO), or other metal oxides or metal nitrides. For example, the barrier layer 230 may be an amorphous barrier, such as AlOₓ or TiOₓ, or a crystalline barrier, such as MgO or a spinel (e.g., MgAl₂O₄). Alternatively, the barrier layer 230 may be comprised of Cu or another high conductivity metal or metal alloy. Further, the barrier layer 230 is thin enough that a current through it can be established by quantum mechanical tunneling of conduction electrons. For example, a thickness of the barrier layer 230 may have a thickness ranging from about 0.5 nanometers to about 2 nanometers.

The magnetic stack 300 is formed on the barrier layer 230 of the base stack 200 and comprises a bottom free layer 310, a spacer layer 320 and a top free layer 330. The bottom free layer 310 is overlaid onto the barrier layer 230 of the base stack 200. The bottom free layer 310 may be a single layer or composite wherein each layer is comprised of one or more of Co, Fe, and Ni. Furthermore, there may be a non-magnetic element such as boron (B) in the aforementioned single layer or composite free layer configuration. In some embodiments, the bottom free layer 310 may have a synthetic antiferromagnetic structure such as CoFeB/Ru/CoFe. In some alternative embodiments, the bottom free layer 310 has a laminated structure comprised of a plurality of Co layers and antiferromagnetic (AF) coupling spacer layers formed in an alternating fashion similar to that of the reference layer configuration. In some embodiments, a thickness of the bottom free layer 310 may be less than about 2 nm enable PMA in the bottom free layer 310. In some embodiments, a thickness of the bottom free layer 310 may be less than about 1 nm. In some embodiments, a thickness of the bottom free layer 310 may be less than about 0.5 nm. In some embodiments, the thickness of the bottom free layer 310 may be less than about 100 Angstroms thick to enable PMA in the bottom free layer 310.

The spacer layer 320 is disposed on the bottom free layer 310 and may be a single layer made of metal oxide, such as MgO, silicon oxide (SiOₓ), strontium titanium oxide (SrTiOₓ), barium titanium oxide (BaTiOₓ), calcium titanium oxide (CaTiOₓ), lanthanum aluminum oxide (LaAlOₓ), manganese oxide (MnOₓ), vanadium oxide (VOₓ), AlOₓ, TiOₓ, or hafnium oxide (HfOₓ). In some embodiments, the spacer layer 320 and the barrier layer 230 may be made of the same material. In some embodiments, the spacer layer 320 may be comprised of MgO, so that the bottom free layer 310 may be sandwiched by two MgO layers, including a MgO spacer layer 320 and a MgO barrier layer 230. In such embodiments, a ratio of [Mg] to [O] of the MgO barrier layer 230 may be similar to that of the MgO spacer layer 320, but the disclosure is not limited thereto. In the MgO spacer layer 320, where Mg content is from about 40 atomic % to about 60 atomic % and O content is from about 40 atomic % to about 60 atomic %. In some embodiments, Mg content is about 50 atomic % and O content is about 50 atomic % (i.e., the ratio of [Mg] to [O] is about 1:1) to achieve an improved performance, including thermal stability. The spacer layer 320 has a thickness equal to or less than about 1 nm. In some embodiments, the thickness of the spacer layer 320 may be equal to or less than 0.5 nm. In some embodiments, the thickness of the spacer layer 320 may be equal to or less than about 100 Angstroms. In some embodiments, the thickness of the spacer layer 320 may be equal to or less than about 2.1 Angstroms. In some embodiments, the thickness of the spacer layer 320 may range from about 0.1 Angstroms to about 3 Angstroms to provide sufficient magnetoresistance. In some embodiments, the thickness of the spacer layer 320 may range from about 0.5 Angstroms to about 500 Angstroms. In some embodiments, the thickness of the spacer layer 320 may range from about 1 Angstroms to about 100 Angstroms. In some embodiments, the spacer layer 320 may have a thickness of about 1.5 Angstroms to about 50 Angstroms. In some embodiments, the spacer layer 320 may have a thickness of about 1.7 Angstroms to about 40 Angstroms. In some embodiments, the spacer layer 320 may have a thickness of about 1.9 Angstroms to about 30 Angstroms. In some embodiments, the spacer layer 320 may have a thickness of about 2 Angstroms to about 20 Angstroms. In some embodiments, the spacer layer 320 may have a thickness of about 2.1 Angstroms to about 10 Angstroms. For example, the spacer layer 320 may be made of MgO with a thickness of about 0.5 Angstroms to about 3 Angstroms. In some embodiments, the spacer layer 320 may be made of MgO with a thickness of about 1 Angstroms to about 2.5 Angstroms. In some embodiments, the spacer layer 320 may be made of MgO with a thickness of about 1.5 Angstroms. In some embodiments, the spacer layer 320 may be made of MgO with a thickness of about 1.7 Angstroms. In some embodiments, the spacer layer 320 may be made of MgO with a thickness of about 1.9 Angstroms. In some embodiments, the spacer layer 320 may be made of MgO with a thickness of about 2.1 Angstroms. In some embodiments, the spacer layer 320 may be made of MgO with a thickness of about 2.3 Angstroms. In some embodiments, a ratio of the thickness of the bottom free layer 310 to the thickness of the spacer layer 320 may range from about 2 to about 100 so that the spacer layer 320 can achieve sufficient magnetoresistance. In some embodiments, a ratio of the thickness of the bottom free layer 310 to the thickness of the spacer layer 320 may range from about 10 to about 75. In some embodiments, a ratio of the thickness of the bottom free layer 310 to the thickness of the spacer layer 320 may range from about 15 to about 50.

The top free layer 330 is disposed over the spacer layer 320 and thus the spacer layer 320 is sandwiched by the bottom free layer 310 and the spacer layer 320. The top free layer 330 may be a single layer or composite wherein each layer is comprised of one or more of Co, Fe, and Ni. Furthermore, there may be a non-magnetic element such as boron (B) in the aforementioned single layer or composite free layer configuration. In some embodiments, the top free layer 330 may have a synthetic antiferromagnetic structure such as CoFeB/Ru/CoFe. In some alternative embodiments, the top free layer 330 has a laminated structure comprised of a plurality of Co layers and antiferromagnetic (AF) coupling spacer layers formed in an alternating fashion similar to that of the reference layer configuration. In some embodiments, the thickness of each of the top free layer 330 should be less than about 50 Angstroms thick to enable PMA in the top free layer 330. In some embodiments, the thickness of each of the top free layer 330 should be less than about 20 Angstroms thick to enable PMA in the top free layer 330. In some embodiments, the top free layer 330 may have the same structure and the same material as the bottom free layer 310. In some embodiments, the top free layer 330 may have different structures and different materials from the bottom free layer 310. In some embodiments, a ratio of the thickness of the top free layer 330 to the thickness of the spacer layer 320 may range from about 2 to about 100 so that the spacer layer 320 can achieve sufficient magnetoresistance. In some embodiments, a ratio of the thickness of the top free layer 330 to the thickness of the spacer layer 320 may range from about 10 to about 75. In some embodiments, a ratio of the thickness of the top free layer 330 to the thickness of the spacer layer 320 may range from about 15 to about 50.

The capping layer 400 is formed on the top free layer 330 of the magnetic stack 300. For example, the capping layer 400 may include a thin metal-oxide or metal-nitride layer. The metal in the metal-oxide (or metal-nitride) capping layer includes beryllium (Be), magnesium (Mg), aluminium (Al), titanium (Ti), tungsten (W), germanium (Ge), platinum (Pt) and their alloy, which can used to protect the free layers 310 and 330 in the magnetic stack 300 during subsequent process steps such as a chemical mechanical polish process. Other elements may be chosen for the capping layer. In another embodiment, the capping layer 400 may be a metal oxide to generate interfacial perpendicular anisotropy along a top surface of the magnetic stack 300 and enhance PMA within the top free layer 330. According to one aspect of the present disclosure, the capping layer 400 may be comprised of MgO, so that the top free layer 330 may be sandwiched by two MgO layers, including a MgO spacer layer 320 and a MgO capping layer 400. In such embodiments, the ratio of [Mg] to [O] of the MgO capping layer 400 may be similar to that of the MgO spacer layer 320, but the disclosure is not limited thereto. In some embodiments, the thickness of the capping layer 400 is in a range from about 3 angstroms to about 20 angstroms. The capping layer 400 may be deposited by PVD, ALD, e-beam or thermal evaporation, or the like.

The top electrode 500 is formed on the capping layer 400 and may be electrically coupled to a second metallization layer (not shown) of the BEOL metallization stack 10B through a second via 12. The second via 12 may extend from the top electrode 500, through an inter-metal dielectric (IMD) layer (not shown), to the second metallization layer of the BEOL metallization stack 10B. The second via 12 may be, for example, a metal, such as copper, gold or tungsten. The top electrode layer 500 may be formed of a conductive material, such as, for example, titanium nitride, tantalum nitride, titanium (Ti), tantalum (Ta), ruthenium (Ru), platinum (Pt), tungsten (W), aluminum (Al), copper (Cu), or a combination of one or more of the foregoing. In some embodiments, the material of the top electrode 500 may be identical to or different from the material for the bottom electrode 100. Further, the top electrode layer 500 may be formed with a thickness of, for example, about 10 nm to about 100 nm. An exemplary formation method of the top electrode layer 500 includes sputtering, PVD, ALD, e-beam or thermal evaporation, or the like.

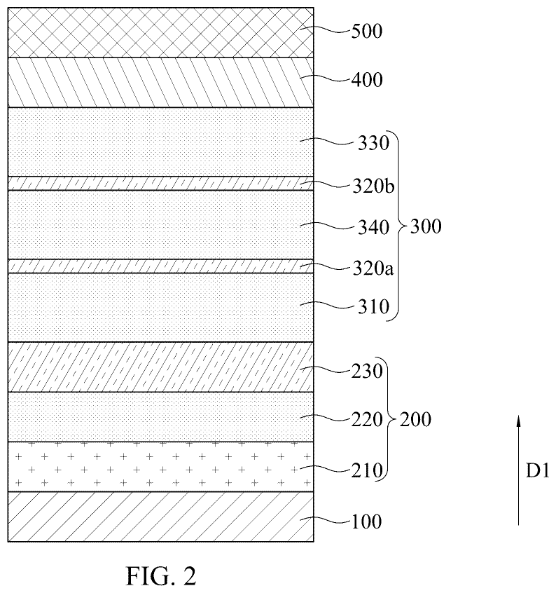

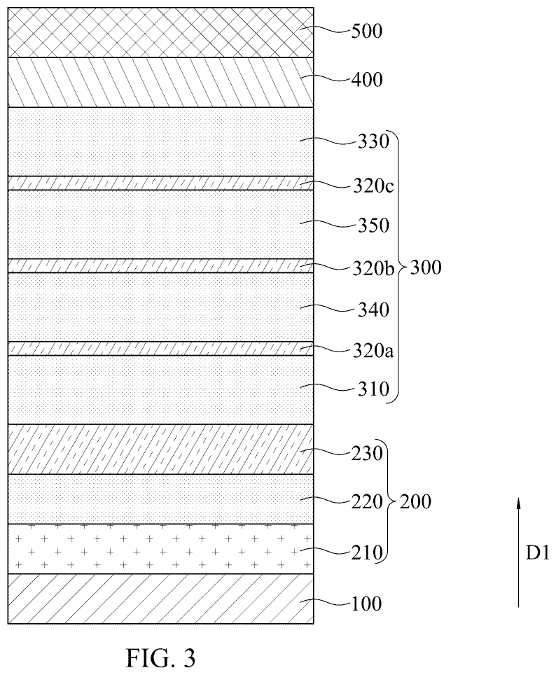

In some another embodiments, the magnetic stack 300 may further comprise one or more internal free layers. As shown in FIG. 2, an internal free layer 340 is formed between the bottom free layer 310 and the top free layer 330, a spacer layer 320a is formed between the internal free layer 340 and the bottom free layer 310, and a spacer layer 320b is formed between the internal free layer 340 and the top free layer 330, so the spacer layers 320a and 320b separate the internal free layer 340 from the bottom free layer 310 and the top free layer 330. FIG. 2 depicts a dual synthetic anti-ferromagnetic (SAF) configuration, which will further improve thermal stability. As shown in FIG. 3, two internal free layers 340 and 350 are formed between the bottom free layer 310 and the top free layer 330, a spacer layer 320a is formed between the internal free layer 340 and the bottom free layer 310, a spacer layer 320c is formed between the internal free layer 350 and the top free layer 330, and a spacer layer 320b is formed between the internal free layers 340 and 350. FIG. 3 depicts a triple synthetic anti-ferromagnetic (SAF) configuration, which will further improve thermal stability. In some embodiments, the thickness of each of the internal free layers 340 should be less than about 50 Angstroms thick to enable PMA in the internal free layers 340. In some embodiments, the thickness of each of the internal free layers 340 should be less than about 20 Angstroms thick to enable PMA in the internal free layers 340.

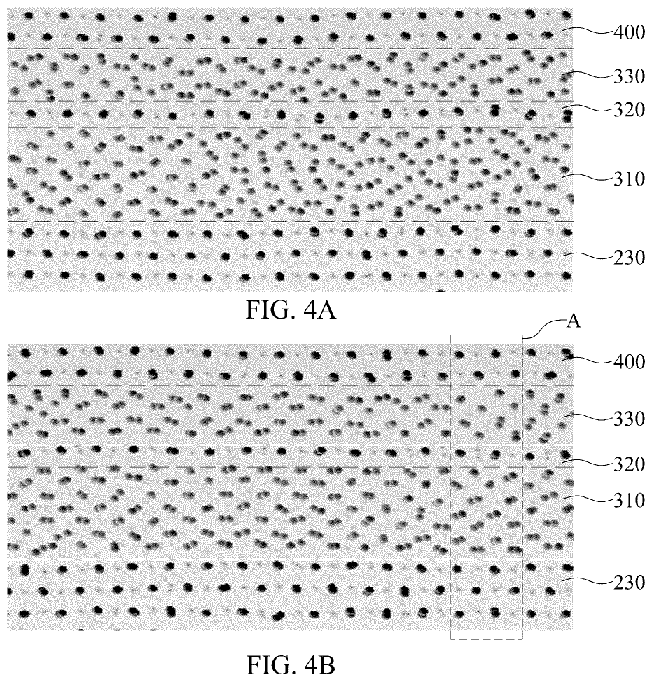

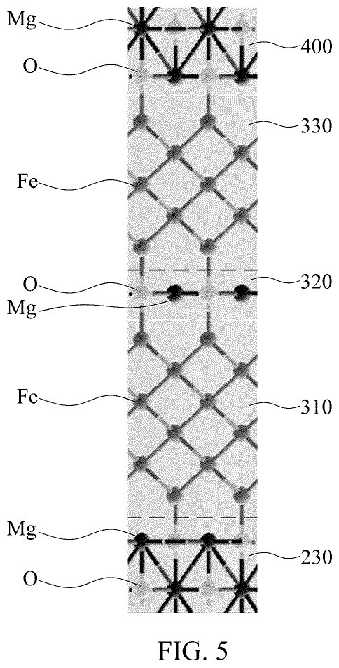

FIG. 4A shows a distribution of atoms in the spacer layers 320 before performing an annealing process and FIGS. 4B and 5 show a distribution of atoms in the spacer layers 320 after performing an annealing process at about 400° C. The spacer layer 320 can be made of MgO including about 50 atomic % magnesium atoms (Mg) and to about 50 atomic % of oxygen atoms (O). The top free layer 330 and the bottom free layer 310 can include iron atoms (Fe). The barrier layer 230 and the capping layer 400 can also include MgO. At atomic level, the distribution of atoms in the spacer layer comprised of metal oxides substantially remains the same before and after performing the annealing process, which indicates that the atoms of the spacer layers 320 would not diffuse to other free layers, such as the bottom free layer 310 and the top free layer 330 adjacent to the spacer layers 320 as shown in FIGS. 4B and 5. Therefore, the spacer layer 320 made of a metal oxide would not dissolve after the annealing process and thus the material for the spacer layer 320 would not diffuse into other layers, so that the performance of the free layers 310, 330, 340 and 350 as shown in FIGS. 1 to 3 can be retained and thus the magnetic properties, such as iPMA and Aₑₓ can be improved compared to a metal spacer layer.

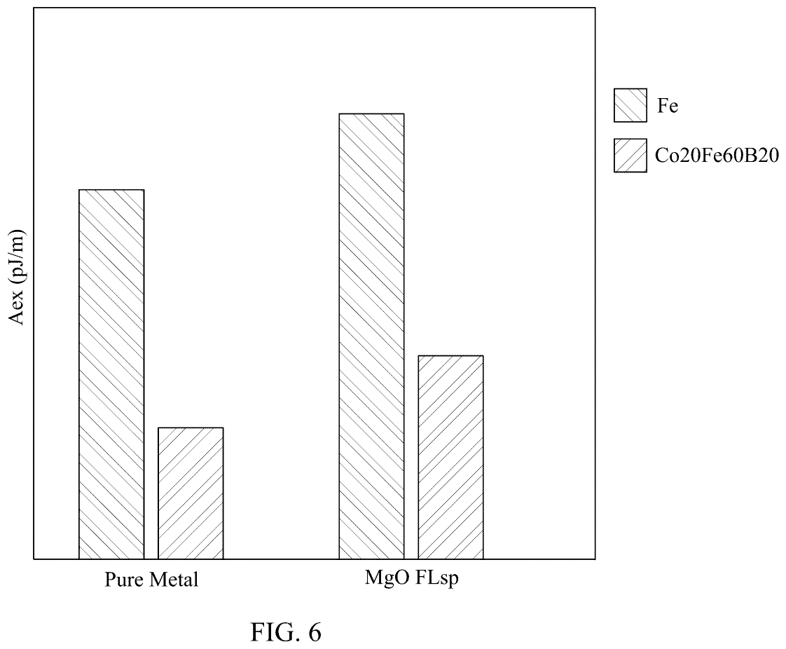

In some embodiments using MgO as the spacer layer 320, due to the stable lattice of MgO, the presence of a MgO spacer layer 320 with a thickness from about 1 Angstroms to about 3 Angstroms in the magnetic stack 300 to separate the free layers would achieve improved properties. As shown in FIG. 6, the presence of a MgO spacer layer between free layers (made of Fe or Co₂₀F₆₀B₂₀) achieve higher Aₑₓ compared with the use of a pure metal as a spacer. Therefore, inserting mono-layer MgO to each two free layers in the magnetic stack 300 can maintain Aₑₓ within the free layers, which helps magnetic domains switch more coherently, so that the semiconductor memory structure would achieve enhanced switching speed. The concentration and location of Mg atoms and O atoms can be detected by thin film metrology tools, such as energy-dispersive X-ray spectroscopy (EDS), secondary ion mass spectroscopy (SIMS), transmission electron microscopy (TEM) and so on.

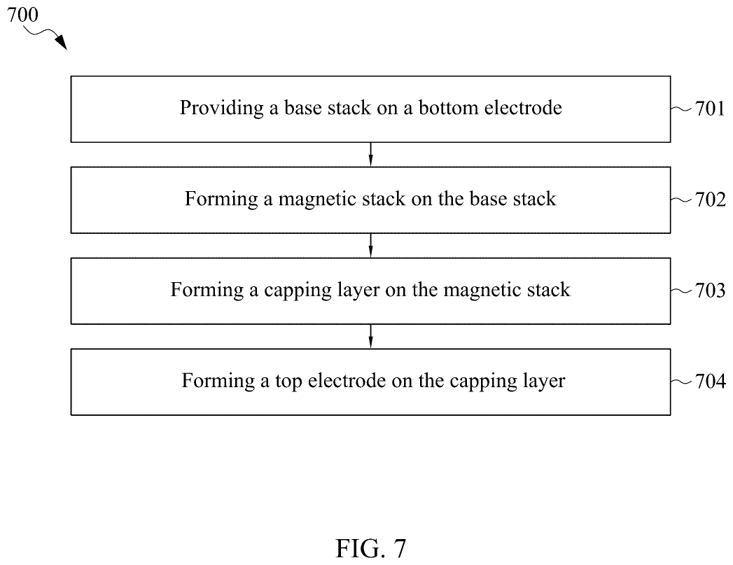

FIG. 7 is a flowchart representing a method 700 of manufacturing a semiconductor memory structure according to various aspects of the present disclosure in accordance with some embodiments. In some embodiments, the method 700 of manufacturing the semiconductor memory structure includes a number of operations (701, 702, 703 and 704). The method 700 of manufacturing the semiconductor memory structure will be further described according to one or more embodiments. It should be noted that the operations of the method 700 may be rearranged or otherwise modified within the scope of the various aspects. It should further be noted that additional processes may be provided before, during, and after the method 700, and that some other processes may be only briefly described herein.

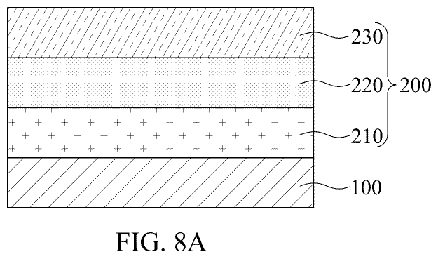

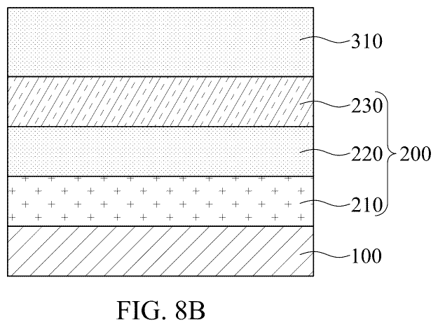

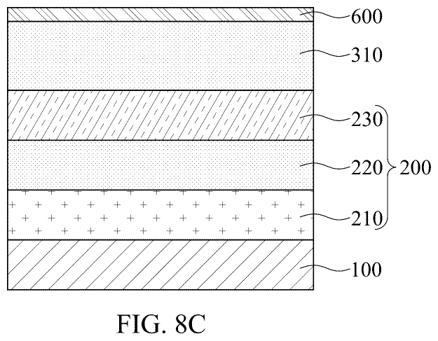

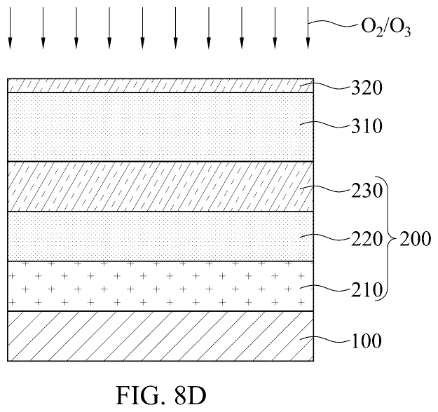

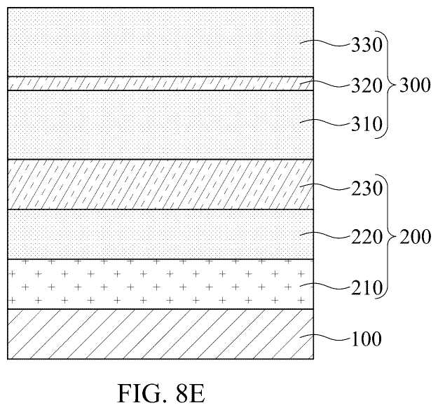

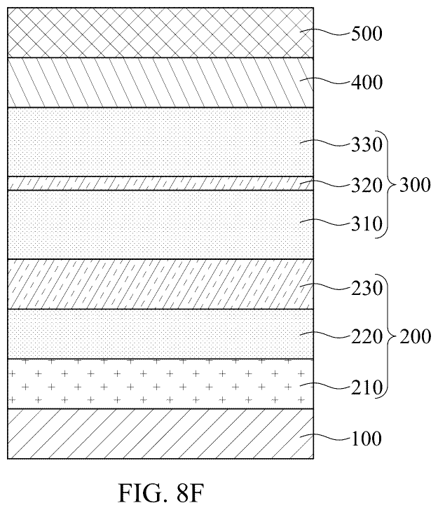

As shown in FIG. 8A, method 700 begins at operation 701 by providing a base stack 200 on a bottom electrode 100, in which the bottom electrode 100 is provided first and the base stack 200 including a seed layer 210, a reference layer 220 and a barrier layer 230 are sequentially deposited on the bottom electrode 100.

Method 700 continues with operation 702, in which a magnetic stack 300 is formed on the base stack 200. To form the magnetic stack 300, two or more free layers are deposited over the base stack 200 and one or more spacer layers are formed between the free layers so that every spacer layer is sandwiched by two free layers. As shown in FIG. 8B, a first free layer is formed on the barrier layer 230 of the base stack 200, which serves as a bottom free layer 310, also the lowest layer of the magnetic stack 300. FIGS. 8C and 8D show the process for forming a spacer layer 320 on the bottom free layer 310, in which a metal layer 600 including Mg, Si, Ba, Ti, Sr, Ca, La, Al, Mn, V, Al, Ti, Hf or a combination thereof is deposited by sputtering a metal material on the bottom free layer 310 (as shown in FIG. 8C), and an oxidation process (including introducing O₂/O₃ gas) flow or introducing oxygen plasma) is performed to oxidize the metal layer 600 to form a metal oxide spacer layer 320 (as shown in FIG. 8D), such as MgO, SiOₓ, SrTiOₓ, BaTiOₓ, CaTiOₓ, LaAlOₓ, MnOₓ, VOₓ, AlOₓ, TiOₓ, or HfOₓ. For example, a Mg layer can be deposited on the bottom free layer 310 and, after performing an oxidation process, a MgO spacer layer 320 is formed.

More free layers and spacer layers may be formed sequentially by repeating the process for forming the bottom free layer 310 and the spacer layer 320 to form the magnetic stack 300 as shown in FIGS. 2 and 3. The uppermost free layer formed in the magnetic stack 300 on a spacer layer 320 serves as a top free layer 330, as shown in FIG. 8E in accordance with some embodiments.

At operation 703, as shown in FIG. 8F, a capping layer 400 is formed on a top surface of the magnetic stack 300. An oxide that serves as the capping layer 400 or as a lower layer in the capping layer 400 may be advantageously used to promote PMA in the top free layer 330 through an oxide/magnetic material interfacial interaction.

Also referring to FIG. 8F, at operation 704, a top electrode 500 is formed on the capping layer 400 to complete an MTJ stack, and to continue the fabrication of the semiconductor memory structure in accordance with some embodiments.

The layers, including the seed layer 210, the reference layer 220 and the barrier layer 230 of the base stack 200, the bottom free layer 310, the spacer layer 320 and the top free layer 330 of the magnetic stack 300 and the capping layer 400, formed between the bottom electrode layer 100 and the top electrode layer 500 form a MTJ structure. All of the layers in the MTJ structure described herein may be formed in a sputter deposition system such as an Anelva C-7100 thin film sputtering system or the like which typically includes three physical vapor deposition (PVD) chambers each having 5 targets, an oxidation chamber, and a sputter etching chamber. At least one of the PVD chambers is capable of co-sputtering. Typically, the sputter deposition process involves an argon sputter gas with ultra-high vacuum and the targets are made of metal or alloys. All of the layers of the MTJ structure may be formed after a single pump down of the sputter system to enhance throughput.

The MTJ structure may be annealed by applying a temperature between 300° C. and about 500° C. for a period of 30 minutes to 5 hours using an oven, or for only a few seconds when a rapid thermal anneal oven is employed.

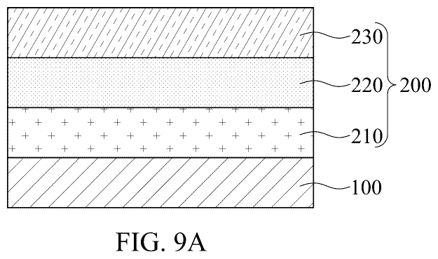

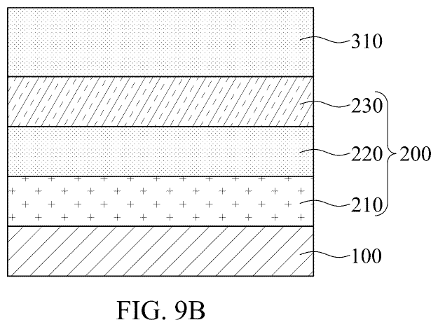

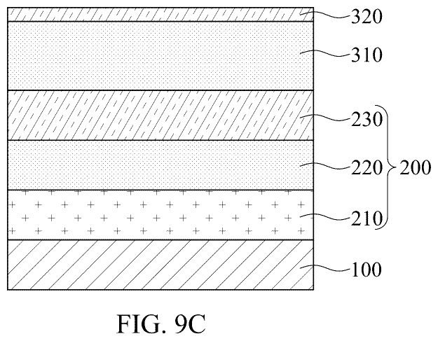

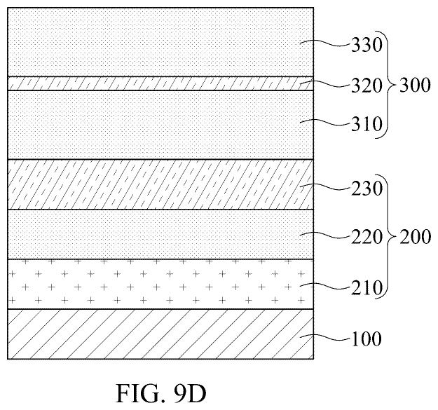

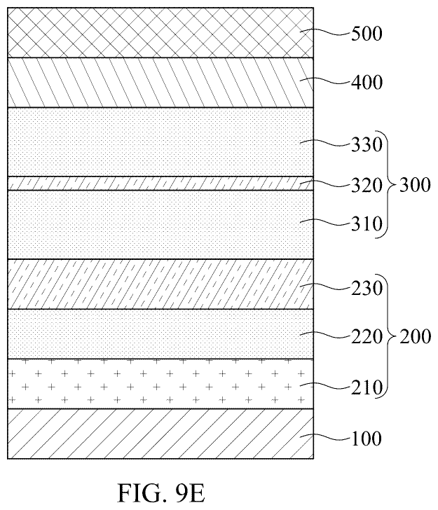

FIGS. 9A to 9E illustrate method 700 of manufacturing a semiconductor memory structure according to various aspects of the present disclosure in accordance with some another embodiments.

As shown in FIG. 9A, a base stack 200 is formed on a bottom electrode 100 (operation 701), in which the bottom electrode 100 is provided first and the bottom electrode 100 including a seed layer 210, a reference layer 220 and a barrier layer 230 are sequentially deposited on the bottom electrode 100.

At operation 702, as shown in FIGS. 9B to 9D, a magnetic stack 300 can be formed on the base stack 200 by forming two or more free layers 310 and 330 and one or more spacer layers 320 alternatively over the base stack 200. A bottom free layer 310 is formed on a top of the base stack 200 and serves as the lowest layer of the magnetic stack 300. Formation of the spacer layer 320 includes depositing a metal oxide on the bottom free layer 310 as shown in FIG. 9C, for example, by radio frequency (RF) sputtering or laser pulse deposition and the like. For example, MgO can be directly sputtered on a free layer as a spacer layer 320. A top free layer 330 is formed on the spacer layer 320 and serves as the uppermost layer of the magnetic stack 300.

A capping layer 400 is formed on the magnetic stack 300 at operation 703 as shown in FIG. 9D and a top electrode 500 is formed on the capping layer 400 at operation 704 as shown in FIG. 9E.

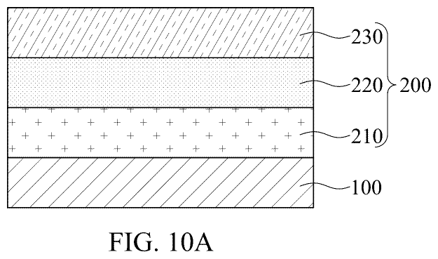

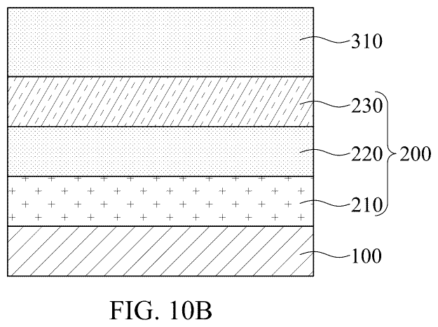

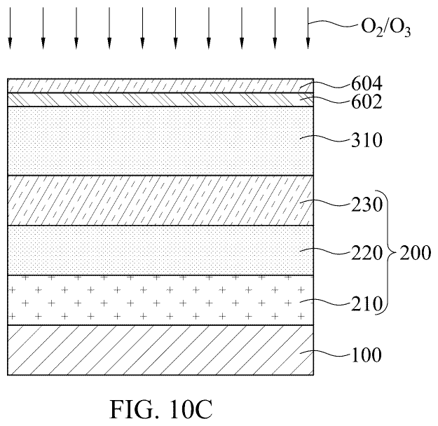

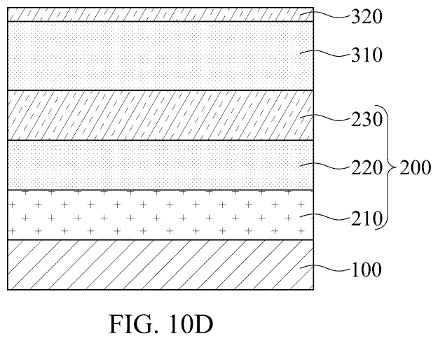

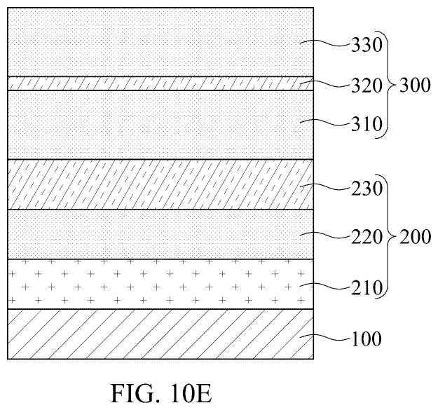

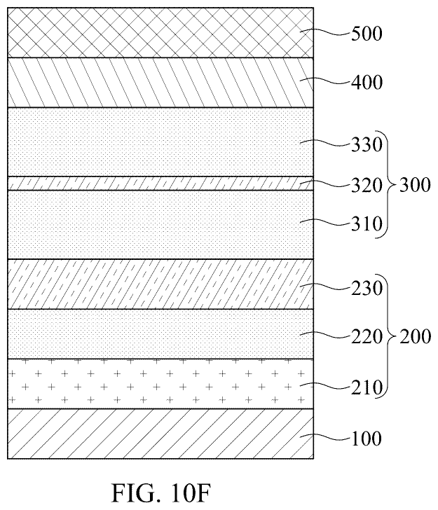

FIGS. 10A to 10F illustrate method 700 of manufacturing a semiconductor memory structure according to various aspects of the present disclosure in accordance with some another alternative embodiments.

As shown in FIG. 10A, a base stack 200 is formed on a bottom electrode 100 (operation 701), in which the bottom electrode 100 is provided first and the bottom electrode 100 including a seed layer 210, a reference layer 220 and a barrier layer 230 are sequentially deposited on the bottom electrode 100.

At operation 702, as shown in FIGS. 10B to 10E, a magnetic stack 300 can be formed on the base stack 200 by forming two or more free layers 310 and 330 and one or more spacer layers 320 alternatively over the base stack 200. A bottom free layer 310 is formed on a top of the base stack 200 as shown in FIG. 10B and serves as the lowest layer of the magnetic stack 300. Formation of the spacer layer 320 includes depositing a first layer 602 on the bottom free layer 310 and depositing a second layer 604 on the first metal layer 602 followed by a natural oxidation process with introduction of O₂ and/or O₃ sputtering gas as shown in FIG. 10C. The first layer 602 may be a metal layer, which serves a precursor while the second layer 604 may be a metal oxide layer or a metal layer. The metal used for forming the first metal layer 602 is identical to that for forming the second layer 604. During the subsequent anneal process, oxygen would diffuse from the second layer 604 into the underneath first layer 602 to form a substantially uniform metal oxide layer, which is the spacer layer 320 as shown in FIG. 10D. If a low RA (resistance×area) value is desired, the thickness and/or oxidation state of the spacer layer 320 may be reduced.

For example, when the spacer layer 320 and the barrier layer 230 are comprised of MgO, such MgO layer is formed by depositing a first Mg layer on the layer underneath the spacer layer 320 or the barrier layer 230 (i.e., the bottom free layer 310/the reference layer 220), then performing a natural oxidation (NOX) process, and finally depositing a second Mg layer on the oxidized first Mg layer. During a subsequent annealing process, the second Mg layer is oxidized to afford a substantially uniform MgO layer.

As shown in FIG. 10E, a top free layer 330 is formed on the spacer layer 320 and serves as the uppermost layer of the magnetic stack 300.

A capping layer 400 is formed on the magnetic stack 300 at operation 703 as shown in FIG. 10E and a top electrode 500 is formed on the capping layer 400 at operation 704 as shown in FIG. 10F.

As mentioned above, two or more spacer layers 320 may be formed as shown in FIGS. 2 and 3. The processes for forming the two or more spacer layers 320 may be identical or different. For example, as shown in FIG. 2, the spacer layer 320a may be formed by directly sputtering MgO on the bottom free layer 310 while the spacer layer 320b may be formed by depositing a Mg layer on the internal free layer 340 and then oxidizing the Mg layer. As shown in FIG. 3, the spacer layer 320a may be formed by depositing a Mg layer on the bottom free layer 310 and then oxidizing the Mg layer; the spacer layer 320b may be formed by depositing a Mg layer on the internal free layer 340 and then depositing a MgO layer with sputtering gas of O₂/O₃; and the spacer layer 320c may be formed by depositing a Mg layer on the bottom free layer 310 and then oxidizing the Mg layer.

The present disclosure relates to a high performance MTJ structure for an ultra-high density MRAM, Spin-Torque MRAM, or Spin Torque Oscillator (STO) device wherein Aₑₓ can be enhanced, and iPMA is better preserved by inserting a spacer layer 320 between any two of free layers. Meanwhile, interfaces between the spacer layer 320 and adjacent free layers are used to generate interfacial perpendicular anisotropy and enhance iPMA. The spacer layers 320 of the present disclosure are made of metal oxides (such as, MgO) formed between the free layers, which can improve exchange coupling (Aₑₓ) and thermal stability in the resulting multilayer magnetic stack 300 because it can be observed that diffusion of atoms of the metal-oxide spacer layers 320 rarely occurs at the interfaces the spacer layer 320 and adjacent free layers. Furthermore, such metal-oxide spacer layers 320 can efficiently separates free layers to target different performance metrics (such as speed, retention and so on).

In some embodiments, a semiconductor memory structure comprising a bottom electrode, a base stack stacking on the bottom electrode along a first direction, a magnetic stack stacking on the base stack along the first direction and comprising two or more free layers separated by one or more spacer layers, wherein each of the one or more spacer layers is sandwiched by two of the two or more free layers, and wherein the spacer layers include a metal oxide; a capping layer formed on an uppermost free layer of the two or more free layers of the magnetic stack; and a top electrode formed on the capping layer.

In some embodiments, a magnetic tunnel junction (MTJ) structure, comprising a magnetic stack stacking on a base stack and comprising a bottom free layer; a first spacer layer formed on the bottom free layer and including a metal oxide; and a top free layer formed over the first spacer layer, wherein a ratio of a thickness of the bottom free layer to a thickness of the first spacer layer ranges from about 5 to about 50; and a ratio of a thickness of the top free layer to the thickness of the first spacer layer ranges from about 5 to about 50.

In some embodiments, a method of manufacturing a semiconductor memory structure comprising forming a base stack on a bottom electrode including sequentially depositing a seed layer, a reference layer and a barrier layer; forming a magnetic stack on the base stack comprising forming two or more free layers over the base stack on the barrier layer of the base stack; and forming one or more spacer layers between each two of the two or more free layers; forming a capping layer on the magnetic stack; and forming a top electrode on the capping layer, wherein the one or more spacer layers include a metal oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor memory structure, comprising
a bottom electrode,
a base stack stacking on the bottom electrode along a first direction,
a magnetic stack stacking on the base stack along the first direction and comprising two or more free layers separated by one or more spacer layers, wherein each of the one or more spacer layers is sandwiched by two of the two or more free layers, and wherein the spacer layers include a metal oxide;
a capping layer formed on an uppermost free layer of the two or more free layers of the magnetic stack; and
a top electrode formed on the capping layer.

2. The semiconductor memory structure of claim 1, wherein the one or more spacer layers include magnesium oxide, silicon oxide, strontium titanium oxide, barium titanium oxide, calcium titanium oxide, lanthanum aluminum oxide, manganese oxide, vanadium oxide, aluminum oxide, titanium oxide, or hafnium oxide.

3. The semiconductor memory structure of claim 1, wherein the one or more spacer layers include magnesium oxide (MgO), wherein Mg content is about 40 atomic % to about 60 atomic % and O content is about 40 atomic % to about 60 atomic %.

4. The semiconductor memory structure of claim 1, wherein each of the one or more spacer layers has a thickness equal to or less than about 1 nm.

5. The semiconductor memory structure of claim 1, wherein each of the one or more spacer layers has a thickness ranging from about 1 Angstroms to about 100 Angstroms.

6. The semiconductor memory structure of claim 1, wherein the base stack comprises:
a seed layer disposed over the bottom electrode;
a reference layer disposed over the seed layer; and
a barrier layer disposed over the reference layer, wherein a lowest free layer of the two or more free layers of the magnetic stack is formed on the barrier layer.

7. The semiconductor memory structure of claim 6, wherein the barrier layer includes a metal oxide.

8. The semiconductor memory structure of claim 6, wherein the barrier layer is comprised of MgO and the one or more spacer layers are comprised of MgO.

9. A magnetic tunnel junction (MTJ) structure, comprising a magnetic stack stacking on a base stack and comprising:
a bottom free layer;
a first spacer layer formed on the bottom free layer and including a metal oxide; and
a top free layer formed over the first spacer layer,
wherein a ratio of a thickness of the bottom free layer to a thickness of the first spacer layer ranges from about 5 to about 50; and a ratio of a thickness of the top free layer to the thickness of the first spacer layer ranges from about 5 to about 50.

10. The MTJ structure of claim 9, further comprising:
one or more internal free layers formed over the first spacer layer;
one or more second spacer layers separating the internal free layers and including a metal oxide; and
a third spacer layer formed on an uppermost internal free layer to separate the uppermost internal free layer from the top free layer.

11. The MTJ structure of claim 10, wherein the first spacer layer, the one or more second spacer layers and the third spacer layer include magnesium oxide, silicon oxide, strontium titanium oxide, barium titanium oxide, calcium titanium oxide, lanthanum aluminum oxide, manganese oxide, vanadium oxide, aluminum oxide, titanium oxide, or hafnium oxide.

12. The MTJ structure of claim 10, wherein the first spacer layer, the one or more second spacer layers and the third spacer layer include magnesium oxide (MgO), wherein Mg content is about 50 atomic % and O content is about 50 atomic %.

13. The MTJ structure of claim 10, wherein each of the first spacer layer, the one or more second spacer layers and the third spacer layer has a thickness equal to or less than about 3 Angstroms.

14. The MTJ structure of claim 10, wherein each of the first spacer layer, the one or more second spacer layers and the third spacer layer has a same thickness.

15. A method of manufacturing a semiconductor memory structure, comprising
forming a base stack on a bottom electrode including sequentially depositing a seed layer, a reference layer and a barrier layer;
forming a magnetic stack on the base stack comprising:
forming two or more free layers over the base stack on the barrier layer of the base stack; and
forming one or more spacer layers between each two of the two or more free layers;
forming a capping layer on the magnetic stack; and
forming a top electrode on the capping layer,
wherein the one or more spacer layers include metal oxides.

16. The method of claim 15, wherein forming one or more spacer layers comprises:
sputtering a metal material on each of the two or more free layer; and
performing an oxidation process to oxidize the metal material to form the metal oxides.

17. The method of claim 15, wherein forming one or more spacer layers comprises depositing a metal oxide on each of the two or more free layer.

18. The method of claim 15, wherein forming one or more spacer layers comprises:
depositing a first metal layer on each of the two or more free layer; and
depositing a second metal layer on the first metal layer followed by an oxidation process.

19. The method of claim 15, wherein the one or more spacer layers include magnesium oxide (MgO).

20. The method of claim 19, wherein each of the one or more spacer layers has a thickness ranging from about 1 Angstroms to about 100 Angstroms.
